(19) United States
(12) Patent Application Publication
(10) Pub. No.: US 2012/0216847 A1
(43) Pub. Date: Aug. 30, 2012

(54) PYROELECTRIC SOLAR TECHNOLOGY APPARATUS AND METHOD

(76) Inventor: SANTOSH KUMAR, San Jose, CA (US)

(21) Appl. No.: 13/036,031

(22) Filed: Feb. 28, 2011

(51) Int. Cl. H01L 31/0216; H01L 35/02; H01L 37/00

(52) U.S. Cl. 136/201; 136/206

(57) ABSTRACT

A method to increase the efficiency of a solar cell comprises applying one of a transparent pyroelectric film and a plurality of films in a stack on a front surface of the solar cell and applying one of an opaque pyroelectric film and plurality of films in a stack on another surface of the solar cell. An electromotive force is generated to bias the solar cell such that an open circuit voltage is created. The method also includes increasing a short circuit current through the pyroelectric film. A constant temporal temperate gradient is created in the pyroelectric film to increase the short circuit current with a temperature. The method also includes biasing a p-n junction of the solar cell with the electromotive force produced from the pyroelectric film.

### CLAIM OF PRIORITY

This application claims priority to the following:
U.S. Utility application Ser. No. 12/774,756 titled “Method to improve efficiency of a solar cell” filed on May 6, 2010;
U.S. Provisional Application No. 61/175,914, titled “Method to improve efficiency of a solar cell” filed on May 6, 2009;
U.S. Provisional Application No. 61/307,911 titled “Using re-radiated energy to harvest pyroelectric power” filed on Feb. 25, 2010;
U.S. Provisional Application No. 61/267,492 titled “Using electric field to harvest energy from pyroelectric” filed on Dec. 8, 2009;
U.S. Provisional Application No. 61/263,388 titled “Thermal methods to increase efficiency of photovoltaic power source” filed on Nov. 22, 2009; and
U.S. Provisional Application No. 61/263,328 titled “Method of thermal energy harvesting using pyroelectric” filed on Nov. 20, 2009; the disclosures of which are hereby incorporated by reference.

### FIELD OF TECHNOLOGY

This disclosure relates generally to the technical fields of thermal energy harvesting using pyroelectric, and in one example embodiment, a method, apparatus and system of thermal energy harvesting in solar cells using a pyroelectric is disclosed.

### BACKGROUND

The efficiency of a solar cell may be its capability to convert the solar energy incident on it to electrical energy. The theoretical maximum efficiency of a single junction solar cell may be the ratio of the area of the rectangle with the longer side along the y axis representing the number of photons as a function of incident energy and the shorter side along the x-axis representing the energy to the area under the curve of energy vs. number of incident photons per unit area per second.

For silicon solar cell made of single crystalline silicon the theoretical maximum efficiency may be less than 30%. Remainder of the solar energy incident on a solar cell may be lost as heat.

### SUMMARY

Disclosed are a method, an apparatus and/or system of pyroelectric solar technology.

In one aspect, a method to increase the efficiency of a solar cell includes applying at least one of a transparent pyroelectric film and a plurality of films in a stack on a front surface of the solar cell. The method also includes applying at least one of an opaque pyroelectric film and plurality of films in a stack on another surface of the solar cell and generating an electromotive force to bias the solar cell such that an open circuit voltage is created by establishing at least one of a predetermined voltage and a current to set an appropriate operating point of the solar cell. The method also includes increasing a short circuit current through the pyroelectric film using at least one of a Schottky diode, a Zener diode, an Avalanche diode and a PIN diode. The method also includes creating a constant temporal temperate gradient in the pyroelectric film to increase the short circuit current with a temperature and biasing a p-n junction of the solar cell with the electromotive force produced from the pyroelectric film.

In another aspect, a solar cell includes a pyroelectric film and a semiconductor provided directly on a surface of the solar cell. The solar cell may also include the pyroelectric film applied on the surface of the solar cell comprising the semiconductor.

In yet another aspect, a photovoltaic power generation apparatus includes a solar cell and a current collecting wiring provided on at least one of a transparent pyroelectric film and an opaque pyroelectric film. The photovoltaic power generation apparatus also includes at least one of a semiconductor and pyroelectric film provided directly on the current collecting wiring, wherein the transparent pyroelectric film deposited on a first side of the solar cell, and the opaque pyroelectric film deposited on a second side of the solar cell.

The methods and systems disclosed herein may be implemented in any means for achieving various aspects, and may be executed in a form of a machine-readable medium embodying a set of instructions that, when executed by a machine, cause the machine to perform any of the operations disclosed herein. Other features will be apparent from the accompanying drawings and from the detailed description that follows.

### BRIEF DESCRIPTION OF THE DRAWINGS

The embodiments of this invention are illustrated by way of example and not limitation in the figures of the accompanying drawings, in which like references indicate similar elements and in which:

FIG. 1 is a schematic view of a solar cell with pyroelectric film, according to one or more embodiments.

FIG. 2 is a schematic representation of the vertical view of a solar cell, according to one or more embodiments.

FIG. 3 is a schematic representation of the cross section of an opaque pyroelectric film, according to one or more embodiments.

FIG. 4 is a schematic view of a circuit representing a solar cell, according to one or more embodiments.

FIG. 5 is a schematic representation of the multiple shottky pyroelectric solar cell circuit, according to one or more embodiments.

FIG. 6 is a schematic representation of single shottky circuit, according to one or more embodiments.

FIG. 7 is a schematic representation of solar power generation apparatus, according to one or more embodiments.

Other features of the present embodiments will be apparent from the accompanying drawings and from the detailed description.

### DETAILED DESCRIPTION

Disclosed are a method, an apparatus and/or a system of pyroelectric solar technology. Although the present embodiments have been described with reference to specific example embodiments, it will be evident that various modifications and changes may be made to these embodiments without departing from the broader spirit and scope of the various embodiments.

In one or more embodiments, a pyroelectric material may be a material that produces a voltage across its surface when subjected to a change in temperature and a solar cell may be a solid state device that converts solar energy into electricity. In one or more embodiments, the pyroelectric material may be used with the solar cell to increase the electrical output efficiency of the solar cell. The electrical output efficiency may be a ratio of the electricity produced by the solar cell to the total input solar energy incident on the solar cell. A large percentage of incident energy or photons those are incident on a solar cell that produce heat may not be utilized by the solar cell to produce electricity. Disclosed is a system and method that utilizes thermally conductive materials to convert the heat generated from the incident energy that was not utilized earlier to produce electricity. In one more embodiments, the solar cell may be replaced by other power generation devices. Power generation devices may include devices that generate power to operate an electrical component.

In an example embodiment, one or more layers of pyroelectric material may be deposited on the solar cell. The pyroelectric material may be applied to the solar cell during the manufacturing process and/or applied so that the solar cell may be modified by such application of the pyroelectric to it.

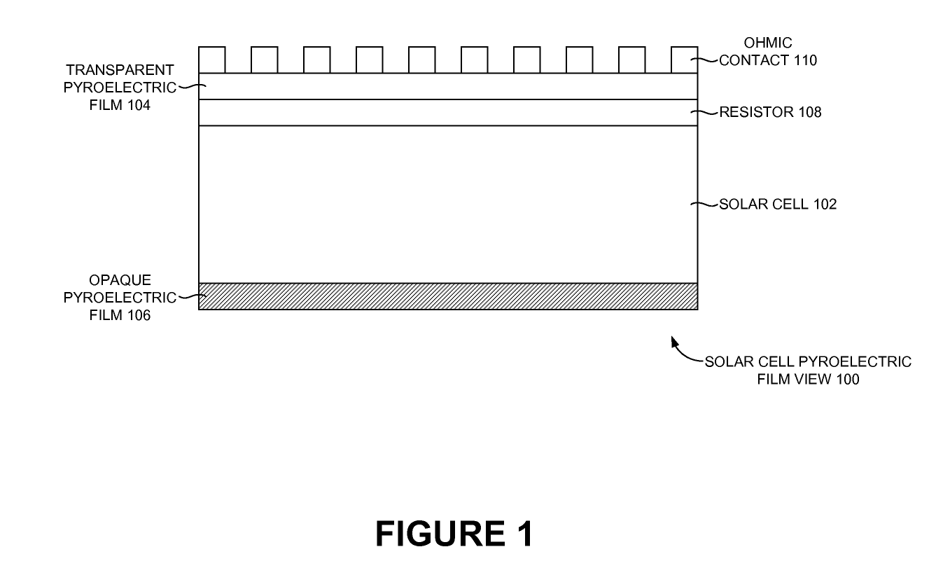

FIG. 1 shows a solar cell pyroelectric view 100, according to one or more embodiments. In one or more embodiments, a transparent pyroelectric film 104 and/or a plurality of pyroelectric films in a stack may be applied to a front surface of the solar cell 102. In one or more embodiments, an opaque pyroelectric film 106 and/or plurality of opaque films in a stack may be applied to another surface of the solar cell 102. In one or more embodiments, the transparent pyroelectric film 104 may be applied on to a resistor 108 that is placed on a front surface of the solar cell 102. In one or more embodiments, ohmic contact 110 may be placed onto the transparent pyroelectric film 104 in form of a semiconductor device. In or more embodiments, a region of the semiconductor device may be prepared to act as an ohmic contact 110. The region of the semiconductor behaving as the ohmic contact 110 may be prepared such that the current-voltage curve of the semiconductor device is linear and symmetric.

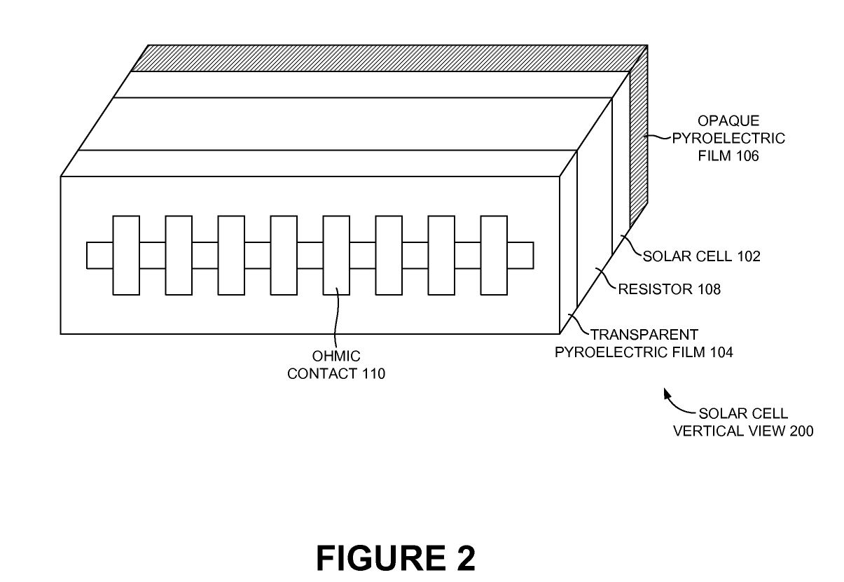

FIG. 2 shows s solar cell vertical view 200, according to one or more embodiments. In one or more embodiments, solar cell 102 may generate heat due to solar irradiance. The solar irradiance may heat the transparent pyroelectric film 104 and/or opaque pyroelectric film 106. In one or more embodiments, due to the heating of the transparent pyroelectric film 104 and/or opaque pyroelectric film 106, an electromotive force may be generated to bias the solar cell 102 such that an open circuit voltage that is created. In one or more embodiments, the open circuit voltage may be established using a predetermined voltage and/or a current to reach an appropriate operating point of the solar cell 102. For example, electromotive force (EMF) produced due to heat may be 50 mV per mJ, with 930 W of solar energy per square meter, approximately 500 mV EMF is produced. In one or more embodiments, the electromotive force may be added to the open circuit voltage of the solar cell 102. For example, a solar cell with open circuit voltage=500 mV that may be without a pyroelectric material that is applied to it will have an effective open circuit voltage of 1000 mV with the pyroelectric material applied to it.

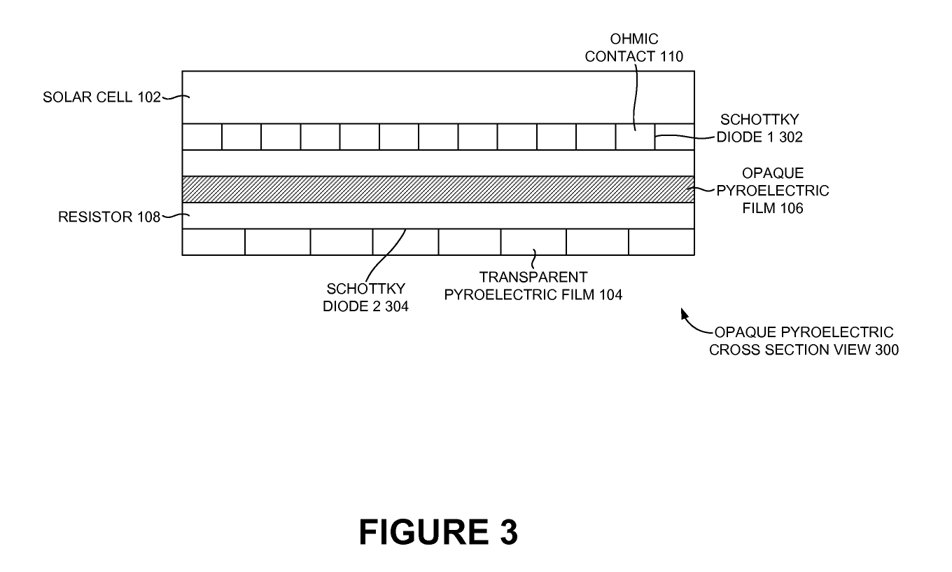

FIG. 3 shows an opaque pyroelectric cross section view 300, according to one or more embodiments. In one or more embodiments, the EMF produced by the opaque pyroelectric material 106 and/or transparent pyroelectric material 104 may be further used to generate electric current using a generation device such as a shottky diode (e.g., shottky diode 1 302 and shottky diode 2 304).

In one or more embodiments, FIG. 3 shows the integration of opaque pyroelectric material 106 in the solar ell 102. In one or more embodiments, shottky diode 1 302 may be formed by deposition of shottky creating metal on the surface of the solar cell 102. Ohmic contacts 110 may be created on the rest of the surface of the solar cell 102 where the shottky is created. In one or more embodiments, opaque pyroelectric film 106 and/or transparent pyroelectric film may be deposited below this surface through deposition techniques such as sputtering and/or screen printing. In one or more embodiments, heat from the Sun and/or wasted heat causes current in the pyroelectric material (e.g., opaque pyroelectric material 106 and transparent pyroelectric material 104), thus increasing the total current of the solar cell 102. In one or more embodiments, resistor 108 may be deposited below the layer of the opaque pyroelectric film 106. In one or more embodiments, when high current passes through the resistor 108, the resistor 108 may produce heat which causes the opaque pyroelectric film 106 which is deposited next to the resistor 108 to produce EMF and charge. The EMF produced may cause current flow in the shottky diode 1 302 and shottky diode 2 304 resulting in increase of the total current through the solar cell 102. In one or more embodiments, additional heat may be generated on the surface of the opaque pyroelectric film 106 which gets heat from the Sun and/or wasted heat, through connections and layers that may not be depicted in the FIG. 3. In one or more embodiments, the heat generated by the current through the resistor 108 caused by the shottky e.g., shottky diode 1 302 may be temporary and it wears down within a short period, such as a second or lesser, in the next small period, e.g., 1 second, current passes through shottky diode 2 304 which also heats a resistor (not shown in Figure), creating the same cycle again. A temporal temperature gradient dT/dt may be created in this manner. In one or more embodiments, temporal temperature gradient dT/dt may be a temporary physical quantity that describes in which direction and at what rate the temperature changes the most in the pyroelectric material of the solar cell 102. In one or more embodiments, the temporal temperature gradient dT/dt may be required to generate EMF through the pyroelectric material. In one or more embodiments, a constant temporal temperature gradient may be created in the opaque pyroelectric film 106 to increase the short circuit current with the increase in temperature of the opaque pyroelectric film 106.

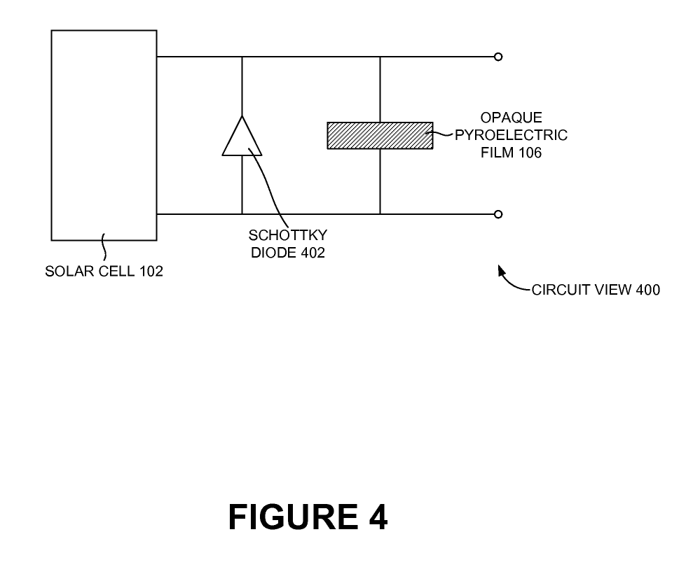

FIG. 4 shows a circuit view 400, according to one or more embodiments. In one or more embodiments, circuit view 400 may represent a method to connect a generation device such as a shottky diode 402 with opaque pyroelectric film 106 and solar cell 102 to increase the short circuit current through the opaque pyroelectric film 106. In one or more embodiments, the short circuit current through the opaque pyroelectric film 106 may be increased using Shottky diode, Zener diode, Avalanche diode, and/or PIN diode. Thus, a sustained temperature variation may be created in the solar cell due to this increase in the short circuit current through the opaque pyroelectric film 106. In one or more embodiments, current source represented by pyroelectric effect may be parallel to current source represented by the solar cell as shown on FIG. 4. In one or more embodiments, EMF produced by the opaque pyroelectric film 106 may be further used to generate electric current using a generation device such as a shottky diode 402. The generated current may increase the short circuit current of the solar cell, thus increasing the power of the solar cell 102.

In one or more embodiments, the solar cell 102 may include the opaque pyroelectric film 106, a semiconductor such as a shottky diode 402 provided directly on the surface of the solar cell 102. In one or more embodiments, the solar cell 102 may also comprise of the opaque pyroelectric film 106 applied on the surface of the semiconductor with the semiconductor.

In one or more embodiments, the temporal temperature gradient may be generated on the solar cell 102 through a standing infra red wave through the opaque pyroelectric film and/or stack of pyroelectric films. In one or more embodiments, the temporal temperature gradient may be generated on the solar cell 102 with pyroelectric material films of varying specific heats and conductivities at a front and/or back of the solar cell. In one or more embodiments, transparent pyroelectric film 104 may comprise of a polyvinylidene fluoride, a tri-glycerin sulphate, a lead zirconate titanate, a stannic titanate, a lithium tantalate, lithium niobate, aluminum nitride, titanium aluminum nitride, barium titanate, and/or barium strontium titanate. In one or more embodiments, opaque pyroelectric film 106 may comprise of a polyvinylidene fluoride, a tri-glycerin sulphate, a lead zirconate titanate, a stannic titanate, a lithium tantalate, lithium niobate, aluminum nitride, titanium aluminum nitride, barium titanate, and/or barium strontium titanate.

In one or more embodiments, the semiconductor diode provided on the surface of the solar cell 102 may comprise of biasing diode, Shottky diode, Zener diode, and/or PIN diode.

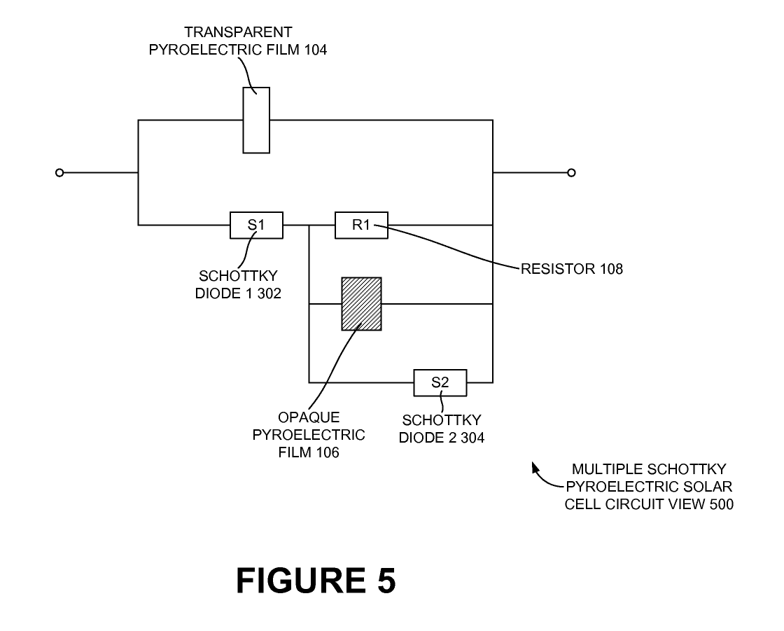

FIG. 5 shows multiple shottky pyroelectric solar cell view 500, according to one or more embodiments. In one or more embodiments, the transparent pyroelectric film 104 may be heated to create a current through the shottky diode 1 302, which heats resistor 108. In one or more embodiments, current through the shottky diode 1 302 may increase the short circuit current of the solar cell 102. In one or more embodiments, the short circuit current through the solar cell 102 may be available for a short period of time. In one or more embodiments, the duration of availability of the short circuit current may vary from less than a second to several seconds. In one or more embodiments, the heat generated by the resistor 108 may be also available for a short period of time and the heat generated by the resistor 108 may cause EMF on the opaque pyroelectric film 106. In one or more embodiments, the opaque pyroelectric film 106 may cause current through shottky diode 2 304, thus increasing the short circuit current of the solar cell 102 for the period when the current through the shottky diode 1 302 goes down. In one or more embodiments, when current through the shottky diode 2 304 is available, another resistor (not shown in FIG. 5) may also be heated. Another resistor that may be heated in turn may add to the heat on the surface of the transparent pyroelectric film 104. In one or more embodiments, surface of the transparent pyroelectric film 104 may receive heat from the Sun and/or other wasted heat, increasing the temporal temperature gradient dT/dt between two surfaces of the transparent film 104. Thus, a continuous increase in the short circuit current through the solar cell 102 may be achieved.

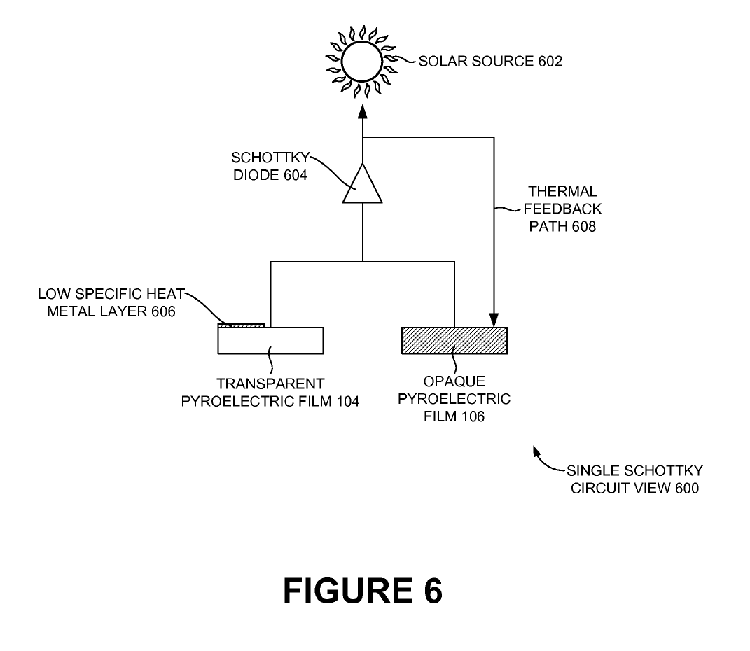

FIG. 6 shows a single shottky circuit view 600, according to one or more embodiments. In one or more embodiments, implementation of FIG. 5 may be accomplished using a single shottky diode 604. Shottky diode 1 302 and shottky diode 2 304 may be combined to use only one shottky diode 604 in FIG. 6. In one or more embodiments, a low specific heat metal layer 606 may be used in contact with the top layer of the transparent pyroelectric film 104. In one or more embodiments, low specific heat metal layer 606 may be heated faster than metal layers with a high specific heat, by sources such as solar source 602. In one or more embodiments, low specific heat metal layer 606 heats very fast and may enhance the temporal temperature gradient dT/dt required by the transparent pyroelectric film 104. In one or more embodiments, a thermal feedback path 608 may be used from the output end of the shottky diode 604 to the opaque pyroelectric film 106.

In one or more embodiments, the power of the solar cell 102 may be a product of the open circuit voltage and the short circuit current. In one or more embodiments, electrical resistance of semiconductor device such as a shottky diode 604 may have a negative increase or reduction when temperature increases. In one or more embodiments, when a negative thermal coefficient of resistance material may be used in the solar cell 102, a reduction in resistance with solar heating increases the shot circuit current through the pyroelectric material thereby increasing the solar power. In one or more embodiments, a low doping material may be used to create negative thermal coefficient of resistance.

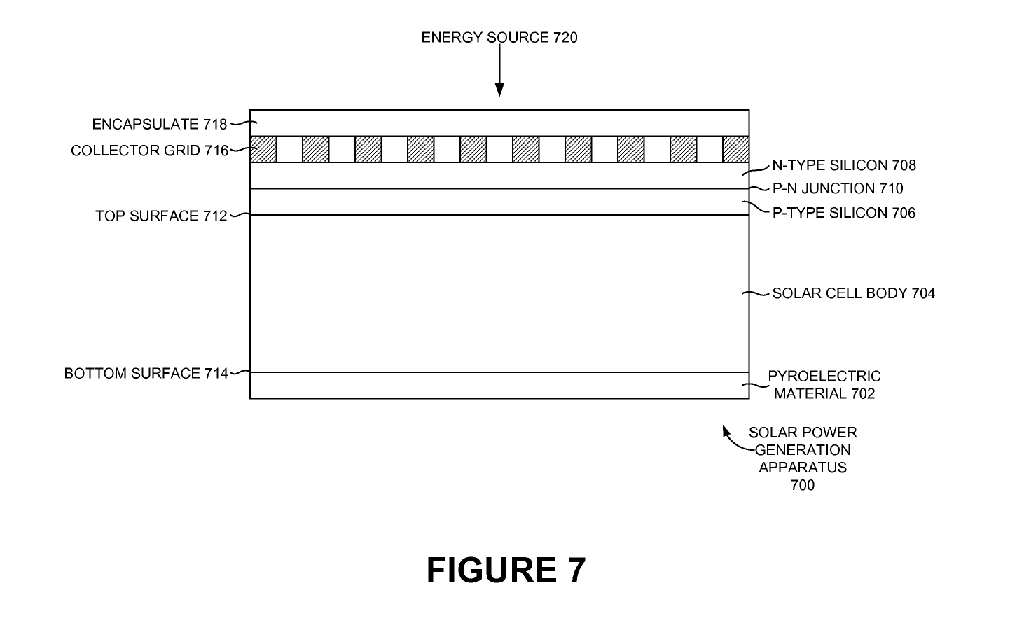

FIG. 7 shows a solar power generation apparatus 700, according to one or more embodiments. In one or more embodiments, solar cell 102 may include a solar cell body 704 with a top surface 712 and a bottom surface 714. In one or more embodiments, a layer of p-type silicon 706 may be disposed on the top surface of the solar cell 102. Additionally, a layer of n-type silicon 708 may be disposed on top of the p-type silicon 706. In one or more embodiments, a p-n junction 710 may be formed in the region between the p-type silicon 706 and the n-type silicon 708. As shown in FIG. 7, a collector grid 716 may be disposed on top of the N-type layer 110 and an encapsulate 718 may be desirably disposed on top of the collector grid 716 to protect the solar cell 102. In one or more embodiments, the collector grid 716 may be a current collector wiring provided on the pyroelectric material 702. In one or more embodiments, a semiconductor e.g., p-n junction 710 and/or a combination of pyroelectric material 702 and semiconductor may be provided directly on the collector grid 716. In one or more embodiments, the transparent pyroelectric film 104 and opaque pyroelectric film 106 may be deposited on the top surface 712 and bottom surface 714 of the solar cell body 704. In another embodiment, the deposition of films on the surfaces may be reversed.

In one or more embodiments, solar cell 102 includes one or more layers of the pyroelectric material 702 disposed on the bottom surface 714 of the solar cell body 704. In one or more embodiments, the pyroelectric material 702 may be disposed on the top surface 712 of the solar cell body 704 and/or disposed on both the top surface 712 and the bottom surface 714 of the solar cell body. In another embodiment, the pyroelectric material 702 may be disposed within and/or between the layers of components of the solar cell body 704. In one or more embodiments, the pyroelectric material 702 may be optically transparent (e.g., transparent pyroelectric film 104) or opaque material (e.g., opaque pyroelectric film 106).

In one or more embodiments, the energy source 720 may be the Sun. In one or more embodiments, sunlight from the Sun may also include ultraviolet rays. In one or more embodiments, sunlight from the energy source 720 may strike the solar cell 102, due to this energy striking the surface of the solar cell 102 heat is generated and collected by the solar cell 102. The heat may travel from the solar cell body 704 towards the pyroelectric material 702. In one or more embodiments, heating of the pyroelectric material 704 may produce an electric field across the pyroelectric material 704 due to the electromotive force generated. However, the pyroelectric material 702 may produce electrical power, only when a temporal thermal gradient dT/dt exists between the top surface 712 and bottom surface 714 of the pyroelectric material 702.

In an example embodiment, a solar cell assembly may include multiple pyroelectric assemblies. The solar cell 102 may include two or more stacks of pyroelectric element assemblies. Each pyroelectric assembly may include an assembly that in turn includes a solar cell which desirably includes two or more stacks of pyroelectric element assemblies. In particular, the assembly may include a first pyroelectric assembly and a second pyroelectric assembly, both of which are disposed on the bottom surface of the solar cell 102. The first pyroelectric assembly desirably may include a first metal layer having a top surface and a bottom surface in which the top surface of the first metal layer may be desirably disposed on a bottom surface 714 of the solar cell body 704. Additionally, a first pyroelectric element may be disposed on the first metal layer and may have a top surface and a bottom surface, whereby the top surface of the first pyroelectric element may be desirably disposed on the bottom surface of the first metal layer. As described above, the layers of pyroelectric elements and metal layers may be stacked in an alternating configuration to maximize the temporal thermal gradient dT/dt in each of the pyroelectric elements in the stack.

A thermally conductive intermediate member may be coupled to the first pyroelectric assembly and the second pyroelectric assembly. In particular, the intermediate conductive member may be coupled to the first metal layer in the first pyroelectric assembly and the last metal layer in the second pyroelectric assembly. The intermediate conductive member may transfer heat from the first metal layer to the last metal layer of the pyroelectric assembly.

In an example embodiment, one or more layers of pyroelectric material may be deposited onto a layer of metal deposited on a substrate, which may be silicon or a similar substrate. A pyroelectric and/or a piezoelectric material may be disposed between two electrodes. The pyroelectric and/or a piezoelectric material may create an electric field that creates positive and negative charges at each of the electrodes. Incident energy onto an electrode may be absorbed by the electrode. Black body radiation may be emitted by the electrode into the pyroelectric and/or a piezoelectric material. The pyroelectric and/or a piezoelectric material may get charged and cause mechanical oscillations in the pyroelectric and/or a piezoelectric material. These oscillations may generate photons. The photons may get reflected by the other electrode. Oncoming and reflected photons may create standing waves that create local thermal oscillations inside the pyroelectric and/or a piezoelectric material that in turn may give rise to electric current.

In an example embodiment, two pyroelectric elements may be used. The first pyroelectric element may be polarized when subjected to heat. The electric field produced due to polarization may be used to reduce the electric field from a second pyroelectric. Electric charge may then be removed from the first pyroelectric using a standard technique such as an RC discharge. As soon as the charge from the first pyroelectric may be discharged, the electric field from the first pyroelectric becomes low and the polarization is unsaturated. The electric field from the second pyroelectric and the heat from the surrounding may increase the polarization in the first pyroelectric. The second pyroelectric may now be discharged using a standard method, such as RC discharge, the above cycle may be repeated continuously to produce continuous power.

In another example embodiment, the pyroelectric material may be applied to the solar cell in the form of a stacked multilayer structure. The Pyroelectric may be for example LiTaO₃. Pyroelectric material stacks may be coupled to the back of a solar cell. In an example embodiment, a plurality of pyroelectric material stacks may be coupled to the solar cell, the solar cell may include a metal layer that is exposed to heat (for e.g., exposed to solar energy). As a result of the change in temperature, positive charges and negative charges may move to opposite ends due to the polarization of the pyroelectric material. Hence, an electric potential may be established. Negative thermal coefficient of resistance (TCR) in a material may cause the reduction of resistance in the material when the material is subjected to heat. In one or more embodiments, doping in a semiconductor may be tailored to create negative TCR. Thus, reduction of the resistance of the material may increase the current that increases the power.

Although the present embodiments have been described with reference to specific example embodiments, it will be evident that various modifications may be made to these embodiments without departing from the broader spirit and scope of the various embodiments.

In addition, it will be appreciated that the various operations, processes, and methods disclosed herein may be embodied in a machine-readable medium and/or a machine accessible medium compatible with a data processing system (e.g., computer devices), and may be performed in any order (e.g., including means for achieving the various operations). Accordingly, the specification and the drawings are regarded in an illustrative rather than a restrictive sense.

What is claimed is:

1. A method to increase the efficiency of a solar cell comprising:
applying at least one of a transparent pyroelectric film and a plurality of films in a stack on a front surface of the solar cell;
applying at least one of an opaque pyroelectric film and plurality of films in a stack on another surface of the solar cell;
generating an electromotive force to bias the solar cell such that an open circuit voltage is created by establishing at least one of a predetermined voltage and a current to set an appropriate operating point of the solar cell;
increasing a short circuit current through the pyroelectric film using at least one of a Schottky diode, a Zener diode, an Avalanche diode and a PIN diode;
creating a constant temporal temperate gradient in the pyroelectric film to increase the short circuit current with a temperature; and
biasing a p-n junction of the solar cell with the electromotive force produced from the pyroelectric film.

2. A solar cell comprising:
a pyroelectric film;
a semiconductor provided directly on a surface of the solar cell; and
the pyroelectric film applied on the surface of the solar cell comprising the semiconductor.

3. The Solar cell of claim 1 where the temporal temperature gradient is generated by standing IR wave through the stack of pyroelectric films.

4. The solar cell of claim 1 where the temporal temperature gradient is generated by a stack of films with varying specific heats and conductivities on at least one of the surface of the solar cell and another surface of the solar cell.

5. The solar cell of claim 2, wherein the transparent pyroelectric film comprises at least one of a polyvinylidene fluoride, a tri-glycerin sulphate, a lead zirconate titanate, a stannic titanate, a lithium tantalate, lithium niobate, aluminum nitride, titanium aluminum nitride, barium titanate, and barium strontium titanate.

6. The solar cell of claim 2, wherein the opaque pyroelectric film comprises at least one of a polyvinylidene fluoride, a tri-glycerin sulphate, a lead zirconate titanate, a stannic titanate, a lithium tantalate, lithium niobate, aluminum nitride, titanium aluminum nitride, barium titanate, and barium strontium titanate.

7. The solar cell of claim 2, wherein the semiconductor diode provided directly on the surface of the solar cell comprises at least one of a biasing diode, Schottky diode, a Zener diode, and a PIN diode.

8. The solar cell of claim 2, wherein a current source represented by the pyroelectric film is in parallel to a current source represented by the solar cell.

9. The solar cell of claim 2, wherein the transparent pyroelectric film deposited directly below the surface of the solar cell comprising the semiconductor is deposited utilizing at least one of a sputtering and a screen printing.

10. The solar cell of claim 2, wherein the opaque pyroelectric film deposited directly below the surface of the solar cell comprising the semiconductor is deposited utilizing at least one of a sputtering and a screen printing.

11. A photovoltaic power generation apparatus comprising:
a solar cell;
a current collecting wiring provided on at least one of a transparent pyroelectric film and an opaque pyroelectric film;
at least one of a semiconductor and pyroelectric film provided directly on the current collecting wiring, wherein the transparent pyroelectric film deposited on a first side of the solar cell, and the opaque pyroelectric film deposited on a second side of the solar cell.

12. The photovoltaic power generation apparatus of claim 11, wherein the transparent pyroelectric film comprises at least one of a polyvinylidene fluoride, a tri-glycerin sulphate, a lead zirconate titanate, a stannic titanate, a lithium tantalate, lithium niobate, aluminum nitride, titanium aluminum nitride, barium titanate, and barium strontium titanate.

13. The photovoltaic power generation apparatus of claim 11, wherein the opaque pyroelectric film comprises at least one of a polyvinylidene fluoride, a tri-glycerin sulphate, a lead zirconate titanate, a stannic titanate, a lithium tantalite, lithium niobate, aluminum nitride, titanium aluminum nitride, barium titanate, barium and strontium titanate.

14. The photovoltaic power generation apparatus of claim 11, wherein the semiconductor provided directly on the surface of the solar cell comprises at least one of a biasing diode, schottky diode, a zener diode, and a PIN diode.

15. The photovoltaic power generation apparatus of claim 11, wherein the semiconductor diode provided directly on the surface of the solar cell comprises at least more than one of schottky diode, zener diode, and PIN diode.

16. The photovoltaic power generation apparatus of claim 11, wherein a current source represented by the pyroelectric film is in parallel to a current source represented by the solar cell.

17. The photovoltaic power generation apparatus of claim 11, wherein the transparent pyroelectric film deposited directly below the surface of the solar cell comprising the semiconductor is deposited utilizing at least one of a sputtering and a screen printing.

18. The photovoltaic power generation apparatus of claim 11, wherein the opaque pyroelectric film deposited directly below the surface of the solar cell comprising the semiconductor is deposited utilizing at least one of a sputtering and a screen printing.
